(19) United States
(12) Patent Application Publication
(10) Pub. No.: US 2004/0063329 A1
(43) Pub. Date: Apr. 1, 2004

(54) Multi-step local dry etching method for SOI wafer

(75) Inventors: Michihiko Yanagisawa, Sagamihara-city (JP); Kazuyuki Tsuruoka, Zama-city (JP); Yasuhiro Horiike, Nishi-Tokyo-city (JP)

Correspondence Address: MORRISON & FOERSTER LLP, 1650 TYSONS BOULEVARD, SUITE 300, MCLEAN, VA, 22102, US

(73) Assignee: Speedfam Co., Ltd., Ayase-city (JP)

(21) Appl. No.: 10/671,483

(22) Filed: Sep. 29, 2003

(30) Foreign Application Priority Data
Sep. 30, 2002 (JP) 2002-287698

(51) Int. Cl. H01L 21/302

(52) U.S. Cl. 438/706

(57) ABSTRACT

A local dry etching method for a SOI wafer capable of flattening an active silicon layer to a layer thickness of a target at a high throughput and to a required accuracy by using a multi-step local dry etching apparatus wherein the apparatus comprises first and second vacuum chambers, a small diameter nozzle, a large diameter nozzle of a diameter larger than that of the small diameter nozzle, an activated species gas generator for generating activated species gases to be blown out of each of the nozzles, each of feeding devices disposed in each of the vacuum chambers for providing a relative speed between the SOI wafer and each of the nozzles to conduct scanning and transportation device, in which the active silicon layer of the SOI waver is etched in the first vacuum chamber to remove the surface unevenness and the active silicon layer is etched to a required layer thickness in the second vacuum chamber.

This application is based on application No. 2002-287698 filed in Japan, the contents of which are hereby incorporated by reference.

### BACKGROUND OF THE INVENTION

1. Field of the Invention

The present invention concerns a local dry etching method of making an active silicon layer of a SOI wafer (top silicon layer) entirely into a thin film and flattening the surface thereof (making the thickness uniform) by dry etching.

2. Description of the Related Art

A local dry etching method has been known so far as one of fabrication methods for flattening the surface of the silicon wafer. In the local dry etching method, an activated species gas generated by plasmas is jetted out from a nozzle and the jetted out activated species gas is blown to the surface of the silicon wafer. Since silicon is reacted with the activated species gas and removed in the form of a gaseous compound, the thickness of the surface material of the silicon wafer is reduced. In this case, when the nozzle is moved relatively along the surface of the silicon wafer, the reducing amount of the thickness from the surface can be controlled in accordance with the speed. The relative movement is conducted usually by scanning and the surface of the silicon wafer is flattened by controlling a scanning speed corresponding to the previously formed surface unevenness of the silicon wafer.

The SOI wafer (Silicon On Insulator) is obtained by forming an oxide film of silicon on the surface of a silicon substrate and forming a thin film-like silicon (elemental silicon) on the oxide film (for example, by appending). The thus formed silicon is referred to as an active silicon layer or a top silicon layer. The active silicon layer has to be fabricated into a thin film to a required thickness (target film thickness) after the formation thereof and has to be flattened at the surface to a required accuracy (uniform thickness).

Since there is a large difference between the initial film thickness of the active silicon layer and the target film thickness and the fabrication area is as large as over the entire wafer surface, the amount of reducing the thickness is large. Further, since a nozzle of a small diameter has to be used correspondingly for conducting necessary planarization, the thickness reducing performance is poor. Accordingly, in a case of applying the existent local dry etching method for the fabrication of the active silicon layer in the SOI wafer, since this inevitably requires long fabrication time, it is difficult to improve the throughput.

In view of the foregoing problems, the present invention intends to provide a local dry etching method for a SOI wafer capable of conducting planarization of an active silicon layer at a high through into a target film thickness and at required accuracy.

### SUMMARY OF THE INVENTION

The foregoing subject can be attained by the following method. That is, the first feature of the present invention resides in a multi-step local dry etching method for SOI wafers, comprising a first step of locally dry etching the surface of an active silicon layer by a nozzle of a small diameter thereby flattening the unevenness present on the surface of the active silicon layer of a SOI wafer, and a second step of locally etching the active silicon layer flattened by the first step by a nozzle of a large diameter thereby reducing the thickness to a required thickness.

The second feature of the present invention for, the multi-step local dry etching method described above, which conducts each local dry etching in the first step and the second step by scanning each of the nozzles for blowing out an activated species gas at a controlled relative speed along the surface of the active silicon layer while blowing the gas on the surface of the active silicon layer.

In the third feature of the present invention for the multi-step local dry etching method described above, the relative speed is controlled by numerical value control, and the pitch for the scanning in the second step is made larger than the pitch for the scanning in the first step.

In the fourth feature of the present invention for the multi-step local dry etching method described above, the activated species gas comprises a SF₆ gas, NF₃ gas, CF₄ gas or a gas mixture thereof, or a gas mixture thereof with oxygen which is activated by plasmas.

The multi-step local dry etching can be conducted in accordance with the present invention by a multi-step local dry etching apparatus including: a first vacuum chamber, a second vacuum chamber, a small diameter nozzle opened in the first vacuum chamber, a large diameter nozzle opened to the second vacuum chamber, and having a diameter larger than that of the small diameter nozzle, an activated species gas generator for generating an activated species gas blown out of the each of the nozzles, each of feeding devices disposed in each of the vacuum chambers for providing a relative speed along the surface of the SOI wafer between the SOI wafer and each of the nozzles described above to conduct scanning, and a transportation device for taking out the SOI wafer after completion of the planarization processing from the first chamber and transporting the same into the second chamber in which the surface unevenness is removed by etching the active silicon layer of the SOI wafer in the first vacuum chamber and the active silicon layer is etched to a required layer thickness in the second vacuum chamber.

In the second feature of the multi-step local dry etching device according to the present invention described above, each of the first vacuum chamber and the second vacuum chamber is provided as a single unit or plural units relative to the single transportation device.

Other objects and advantages besides those discussed above shall be apparent to those skilled in the art from the description of a preferred embodiment of the invention which follows. In the description, reference is made to accompanying drawings, which form a part thereof, and which illustrate an example of the invention. Such example, however, is not exhaustive of various embodiments of the invention, and therefore reference is made to the claims which follow the description for determining the scope of the invention.

### BRIEF DESCRIPTION OF THE DRAWINGS

The accompanying drawings, which are incorporated in and constitute a part of the specification, illustrate embodiments of the invention and together with the description, serve to explain the principles of the invention.

Preferred embodiments of the present invention will be described in details based on the drawings, wherein

FIG. 1 is an example of a graph showing a relation between spatial wavelength for unevenness and unevenness reducing performance (extent of reducing unevenness) determined on every nozzle diameter;

FIG. 2 is an example of a graph showing a relation between a nozzle diameter and an etching rate;

FIG. 3 is a schematic view for explaining the outline of a multi-step local etching apparatus 100 suitable to practicing of the present invention;

FIG. 4 schematically shows the processing at the first step and the second step depending on the change for the cross section of a SOI wafer;

FIG. 5 is a graph sterically showing measured values for the film thickness of an active silicon layer before the first step;

FIG. 6 is a graph sterically showing measured values for the film thickness of an active silicon layer after the first step; and

FIG. 7 is a graph sterically showing measured values for the film thickness of an active silicon layer after the second step.

### DESCRIPTION OF THE PREFERRED EMBODIMENTS

Preferred embodiments of the present invention are to be described below. In local dry etching, since activated species gases blown out of a nozzle are collided (in contact) on a wafer surface to cause reaction by the collision, the size of the flow, that is, the spot diameter of the activated species gas determines the range (extent) of reduction of the thickness. Unevenness of the initial active silicon layer includes various spatial components (frequency components). In order to remove the unevenness for obtaining flatness at a required accuracy, a flow of activated species gas of a size corresponding to the wavelength components has to be formed. Accordingly, it is necessary to use a nozzle of a diameter as small as possible in order to remove fine unevenness (short wavelength component)

On the other hand, in a case of reducing the thickness of an active silicon layer into that of a target, since the thickness is reduced deeply over the entire surface area, it requires much more amount of thickness reduction—compared with the amount of reduction for the removal of fine unevenness (which may be partially conducted depending on the case). Therefore, for the etching rate, it is more efficient to enlarge the diameter of the activated species gas flow, that is, the nozzle diameter.

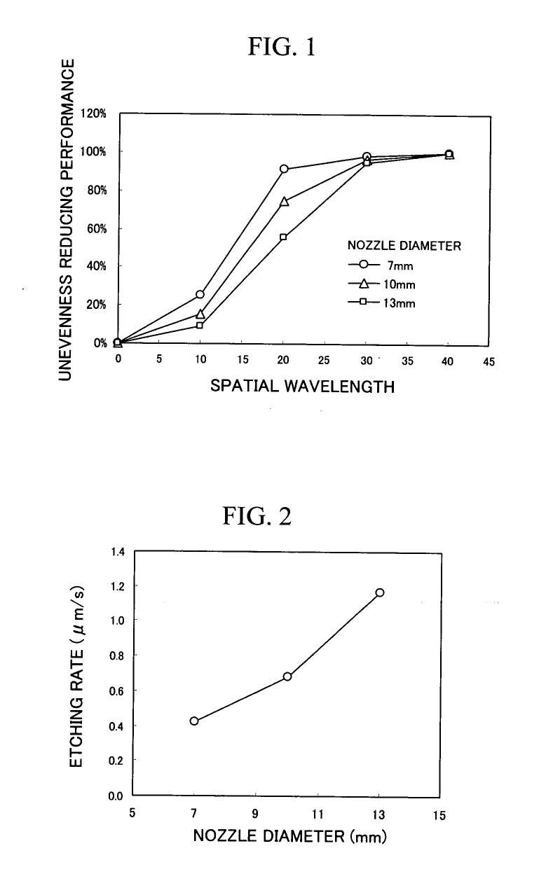

FIG. 1 is an example of a graph showing a relation between a spatial wavelength for unevenness and an unevenness reducing performance (extent of reducing unevenness) determined on every nozzle diameter (nozzle inner diameter for 7 mm, 10 mm and 13 mm, other conditions being identical). It can be seen that the unevenness for the components of the spatial wavelength 20 mm or longer can be substantially removed with the nozzle diameter of 7 mm, whereas the unevenness for components of the spatial wavelength of 20 mm can be removed only by about one-half with the nozzle diameter of 13 mm, and only the unevenness for the components of the spatial wavelength of about 30 mm could be removed substantially completely.

FIG. 2 is an example of a graph showing a relation between a nozzle diameter (nozzle inner diameter for 7 mm, 10 mm and 13 mm, other conditions being identical) and an etching rate (etching speed in view of the entire reduced volume per unit area). It can be seen that the etching rate is only about 0.5 μm/sec when local etching is conducted with a nozzle of 7 mm inner diameter, whereas an etching rate of about 1.2 μm/sec can be obtained with a nozzle of 13 mm inner diameter. An intermediate value is obtained with nozzle of 10 mm diameter.

As can be seen also from the graphs of FIG. 1 and FIG. 2, it is necessary to decrease the nozzle diameter as small as possible for removing fine (short wavelength components) unevenness, while increase the nozzle diameter as much as possible for obtaining a high etching rate.

In view of the above, according to the invention, an active silicon layer can be flattened at a high throughput to a thickness of a target film and at a required accuracy by apply local etching including the first step and the second step.

Multi-Step Local Etching Apparatus

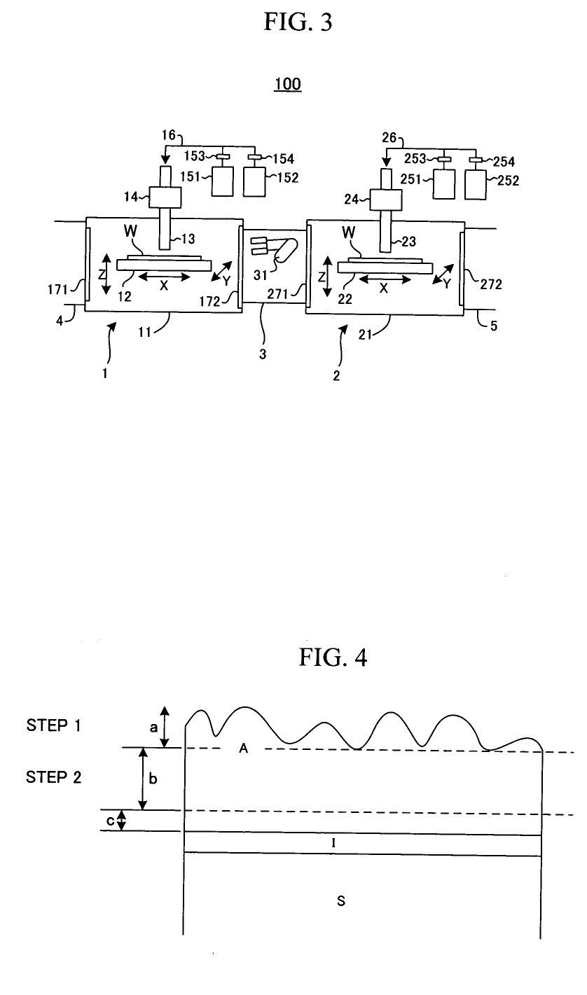

FIG. 3 is a schematic view for explaining the outline of a multi-step local etching apparatus 100 suitable to practicing of the method of the invention. The multi-step local etching apparatus 100 comprises a first local etching device 1 and a second local etching device 2, which are connected by way of a transportation chamber 3.

The first local etching device 1 and the second local etching device 2 have, respectively, a first vacuum chamber 11 and a second vacuum chamber 21. The chambers 11 and 21 have, respectively, a first wafer table 12 and a second wafer table 22 at the inside thereof, on which SOI wafers W are placed and fixed. Each of the wafer tables 12 and 22 can feed wafers in the directions X, Y and Z (vertically, rightward to leftward, and frontward to backward directions in FIG. 3) by way of each sending device not illustrated (for example, NC control feed device).

Further, a small diameter nozzle 13 (for example, of 7 mm inner diameter) is opened in the first vacuum chamber 11, and a large diameter nozzle 13 (for example, of 13 mm inner diameter) is opened in the second vacuum chamber 21, respectively, and activated species gases are brown out of the nozzles 13 and 23. At the outside of each of the vacuum chambers, and at the intermediate portion for each of the nozzles 13 and 23, a first activated species gas generator 14 and a second activated species gas generator 24 are disposed respectively. Microwaves generated by a not-illustrated microwave generator are irradiated to the intermediate portion of the nozzles in each of the activated species gas generator.

Upper ends of the small diameter nozzle 13 and the large diameter nozzle 23 are connected by way of a pipe 16 and a pipe 26 to gas reservoirs 151, 152 and gas reservoirs 251, 252. Near the exit for each of the gas reservoirs, valves 153, 154 and valves 253, 154 are disposed, and gases in any of the reservoirs can be supplied to the upper end of the small diameter nozzle 13 and the large diameter nozzle 23 by opening/closing of the valves. SF₆ gas, NF₃ gas, CF₄ gas, etc. and, depending on the case, oxygen to be mixed therewith are filled in each of the reservoirs.

The first vacuum chamber 11 has a door 171 for the entry of SOI wafers from a entry chamber 4 and a door 172 for the delivery of SOI wafers after removal of unevenness in the first vacuum chamber 11 into a delivery chamber 5. Further, the second vacuum chamber 21 has a door 271 for the entry of SOI wafers after removal of unevenness and a door 272 for the delivery of SOI wafers after being reduced to a target film thickness. The door 172 and the door 271 isolate the transportation chamber 3 from the first vacuum chamber 11 and the second vacuum chamber 21.

A transportation device 31 is a device for taking out a SOI wafer W after planarization from the first vacuum chamber 11 and transporting the same into the vacuum chamber 21 and the device 31 is disposed in the transportation chamber 3 in this embodiment. The transportation device 31 can be adapted to grip the wafer W on the first wafer table 12 and place the wafer directly on the second wafer table 22. Alternatively, it may also be adapted to place the wafer once on a buffer disposed in the first vacuum chamber 11, the second vacuum chamber 21 or the transportation chamber 3 and then placing it on the second wafer table at a predetermined timing.

Further, each of the first vacuum chamber 11 and the second vacuum chamber 21 may not necessarily be a single chamber. That is, first vacuum chamber 11 and second vacuum chamber 21 each of an appropriate number may be arranged around the single transportation chamber 3 such that the transportation device 31 in the transportation chamber 3 can access to any of them. By adapting the ratio between each of the vacuum chambers as one to multiple, multiple to one or multiple to multiple ratio, or by location of the buffer described above, the difference of the tact time (fabrication time) between each of the local etching devices 1 and 2 can be absorbed.

Each of the first vacuum chamber 11, the second vacuum chamber 21 and, optionally, the transportation chamber 3 is connected with a vacuum pump (not illustrated) to evacuate the inside (pressure reduction) and control the vacuum degree to an optimum level respectively.

Operation and Manipulation

It is assumed that each of the first vacuum chamber 11, the second vacuum chamber 21, the transportation chamber 3, the entry chamber 4 and the delivery chamber 5 is depressurized to an identical extent, and the doors 171, 172, 271, 272 are closed. Further, one or more SOI wafers have already been entered into the delivery chamber 4.

First Step

The door 172 is opened, the first step is completed, and a SOI wafer after having been removed with unevenness (preceding SOI wafer) is detached by the transportation device 31 from the wafer table 12 and then taken into the transportation chamber 3. Then, the door 172 is closed while the door 171 is opened. A not illustrated transportation device takes out a sheet of SOI wafer from the entry chamber 4 and places it onto the emptied the first wafer table 12. The SOI wafer is held by an electrostatic chuck (not illustrated) of the first water table 12. Then the door 171 is closed.

The valve 153 and/or valve 154 are opened and gases in the reservoir 151 and/or reservoir 152 are introduced by way of the pipe 16 to the small diameter nozzle 13. About at the same time, microwaves generated in a not illustrated microwave generator are introduced to the activated species gas generator 14 and the gases introduced into the small diameter nozzle 13 are converted into plasmas to generate activated species gases. The activated species gases blow out from the lower end of the small diameter nozzle 13 to the direction of the SOI wafer below.

The first wafer table 12 is fed by a not illustrated feeding device from the small diameter nozzle 13 to a position therebelow spaced by a predetermined distance (position in the direction Z). Then, it is sent pitchwise in the direction X each at a predetermined scanning pitch, and also sent at a controlled speed in the direction Y during pitchwise sending. That is, the SOI wafer is scanned.

Unevenness on the surface of an active silicon layer of the SOI waver has been previously measured. The scanning pitch and the feeding speed in the direction Y suitable to the removal of surface unevenness are previously calculated based on the measured data, the diameter of the small diameter nozzle to be used and other etching conditions, and the feeding device (not illustrated) is controlled (NC controlled) based on the result of calculation.

Second Step

As described above, when the first step for the removal of unevenness has been completed, the door 172 is opened. The transportation device 31 detaches the SOI waver removed with the unevenness from the first wafer table 12 and takes it into the transportation chamber 3. The door 172 is closed. After the SOI waver is taken into the transportation chamber 3, the door 271 of the second vacuum chamber 21 is opened.

The transportation device 31 places the SOI wafer on the second wafer table 22 which has already been emptied. The SOI wafer is held by an electrostatic chuck (not illustrated) of the second wafer table 22. Then, the door 271 is closed.

The valve 253 and/or valve 254 are opened and gases in the reservoir 251 and/or reservoir 252 are introduced by way of the pipe 26 to the large diameter nozzle 23. About at the same time, microwaves generated in a not illustrated microwave generator are introduced to the activated species gas generator 24 and the gases introduced into the large diameter nozzle 23 are converted into plasmas to generate activated species gas. The activated species gases blowout from the lower end of the large diameter nozzle 23 to the direction of the SOI wafer below.

The second wafer table 22 is fed by a not illustrated feeding device from the large diameter nozzle 23 to a position therebelow spaced by a predetermined distance (position in the direction Z). Then, it is sent pitchwise in the direction X each at a predetermined scanning pitch, and sent at a controlled speed in the direction Y during pitchwise sending. That is, the SOI wafer is scanned.

The scanning in this step is a processing for removing the material uniformly for a predetermined thickness from the surface of the active silicon layer. Accordingly, the scanning pitch and the feeding speed in the direction Y have been previously calculated such that etching is conducted uniformly for the entire portion based on the diameter of the large diameter nozzle 23 to be used and other etching conditions, and the feeding device (not illustrated) is controlled (NC controlled) based on the result of calculation. Since the large diameter nozzle is used, the scanning pitch is set larger compared with that in the planarization treatment and since the diameter of the nozzle is large, high processing speed can be obtained.

When the active silicon layer is etched to a predetermined film thickness and fabrication in the second step has been completed, the door 272 is opened, and a not illustrated transportation device takes out the SOI wafer from the second table 22 and takes it into the delivery chambers. Subsequently, the SOI wafer is transferred to a succeeding step for another processing.

FIG. 4 schematically shows the processing in the first step and the second step by the change of the cross section of the SOI wafer. As has been described previously, a SOI wafer is prepared by forming a silicon oxide film I on the surface of a single silicon substrate S, forming a thin film-like silicon (elemental) on the oxide film, for example, by bonding, as an active silicon layer A.

In the first step, unevenness on the surface of the active silicon layer A is removed and flattened by local etching. The planarization is conducted by using the small diameter nozzle, and the portion for the region a is selectively removed in accordance with unevenness. Then, in the second step, a portion for the depth b is locally etched from the surface layer of the active silicon layer A after planarization. A large diameter nozzle is used for the local etching and material is removed uniformly from the surface. As a result, the active silicon layer A is left only for the portion of a region c, that is, by a required thickness, and the planarity obtained in the first step is substantially kept as it is on the surface.

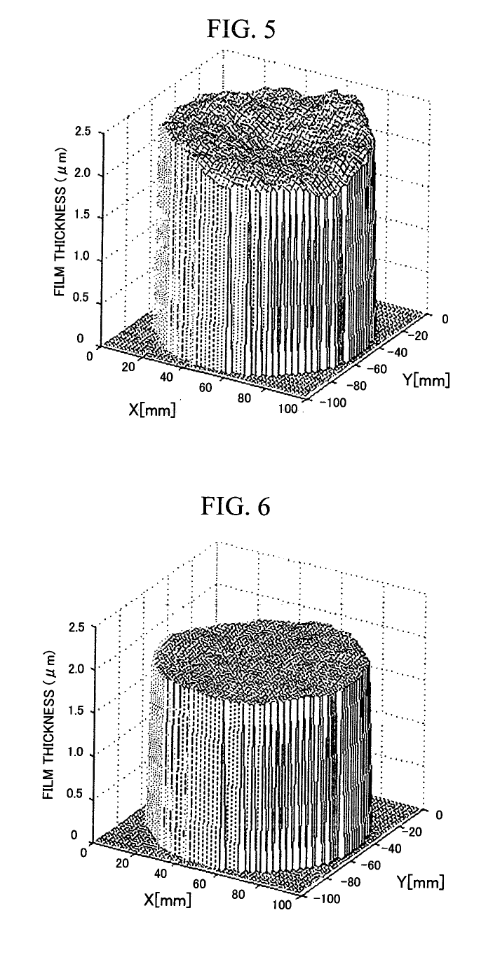

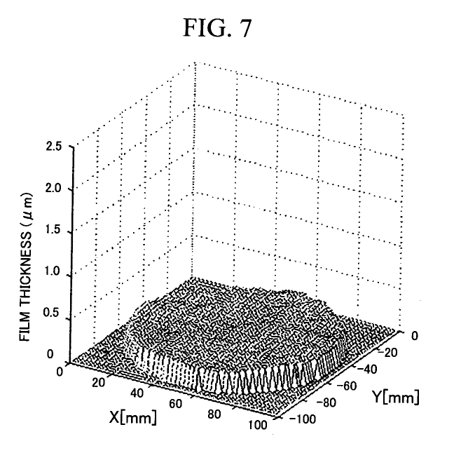

FIG. 5, FIG. 6, and FIG. 7 are graphs sterically showing measured values for the thickness of the active silicon layer A before and after the first step and after the second step respectively. In the graph, the unit for the scale is different between the direction Z and the directions X and Y, and the graph is expanded in the vertical direction. Large unevenness present on the surface before the first step as shown in FIG. 5 is fabricated substantially to a planar state although with fine unevenness after the step 1 as shown in FIG. 6. Further, after the second step, it can be seen that the thickness is reduced uniformly such that the fine evenness is left with the shape being left as it is.

The local dry etching in each of the steps is conducted by scanning at a controlled relative speed along the surface of the active silicon layer while blowing the gas on the surface of the active silicon layer. Further, the relative speed of the scanning is controlled by numerical control and the scanning pitch in the second step is set larger than the scanning pitch in the first step. For the activated species gas, one of SF₆ gas, NF₃ gas and CF₄ gas, or a mixture of such gases or a mixed gas of the gas described above with oxygen activated by plasmas can be used.

The method of the invention is attained not only by the multi-step local etching apparatus having a plurality of vacuum chambers as has been described with reference to FIG. 3, but it is possible to practice them method also in one identical vacuum chamber by using a single local etching device and replacing the small diameter nozzle and the large diameter nozzle.

The present invention can provide an advantageous effect of flattening the active silicon layer of a SOI wafer to a target thickness, at a high throughput and to a require accuracy.

Although only preferred embodiments are specifically illustrated and described herein, it will be appreciated that many modifications and variations of the present invention are possible in light of the above teachings and within the purview of the appended claims without departing from the spirit and intended scope of the invention.

What is claimed is:

1. A multi-step local dry etching method for a SOI wafer including:
a first step of locally dry etching the surface of an active silicon layer by a small diameter nozzle thereby flattening unevenness present on the surface of the active silicon layer of the SOI wafer, and
a second step of locally etching the active silicon layer flattened by the first step by a large diameter nozzle thereby reducing the layer to a required layer thickness.

2. A local dry etching method according to claim 1, which conducts each local dry etching in the first step and the second step by scanning each of the nozzles for blowing out an activated species gas at a controlled relative speed along the surface of the active silicon layer while blowing the gas on the surface of the active silicon layer.

3. A local dry etching method according to claim 1, wherein the relative speed is controlled by numerical value control, and the pitch for the scanning in the second step is made larger than the pitch for the scanning in the first step.

4. A local dry etching method according to claim 1, wherein the activated species gas comprises a SF₆ gas, NF₃ gas, CF₄ gas or a gas mixture thereof, or a gas mixture thereof with oxygen, which is activated by plasmas.

5. A multi-step local dry etching apparatus including,
a first vacuum chamber,
a second vacuum chamber,
a small diameter nozzle opened in the first vacuum chamber,
a large diameter nozzle opened to the second vacuum chamber and having a diameter larger than that of the small diameter nozzle,
an activated species gas generator for generating activated species gases to be blown out of the each of the nozzles,
each of feeding devices disposed in each of the vacuum chambers, for providing a relative speed along the surface of the SOI wafer between the SOI wafer and each of the nozzles described above to conduct scanning, and
a transportation device for taking out the SOI wafer after completion of the planarization processing from the first chamber and transporting the same into the second chamber in which
the surface unevenness is removed by etching the active silicon layer of the SOI wafer in the first vacuum chamber and the active silicon layer is etched to a required layer thickness in the second vacuum chamber.

6. A multi-step local dry etching apparatus according to claim 5, wherein
each of the first vacuum chamber and the second vacuum chamber is provided as a single unit or plural units relative to the single transportation device.
